(19) United States
(12) Patent Application Publication
(10) Pub. No.: US 2025/0259935 A1
(43) Pub. Date: Aug. 14, 2025

(54) ELECTRONIC MODULE

(71) Applicant: SHINDENGEN ELECTRIC MANUFACTURING CO., LTD., Tokyo (JP)

(72) Inventors: Soichiro UMEDA, Saitama (JP); Atsushi KYUTOKU, Saitama (JP)

(21) Appl. No.: 19/046,515

(22) Filed: Feb. 6, 2025

(30) Foreign Application Priority Data
Feb. 14, 2024 (JP) 2024-020368

(51) Int. Cl. H01L 23/538; H01L 23/31; H01L 23/36

(52) U.S. Cl. CPC H01L 23/5385; H01L 23/3107; H01L 23/36

(57) ABSTRACT

An electronic module includes: a first board, a first heat generation part, and a mold resin. The electronic module further includes: a second board that is disposed in a state where the second board is spaced apart from the first board and the first heat generation part; and first heat transfer members that are configured to transfer heat generated from the first heat generation part to the second board. A surface of the first board on a side opposite to a side where the first heat generation part is disposed, and a surface of the second board on a side opposite to a first board side are exposed to the outside of the electronic module. According to the electronic module, heat generated from the first heat generation part can be radiated not only from the first board but also from the second board via the first heat transfer member.

### CROSS REFERENCE TO RELATED APPLICATIONS

This application claims priority to Japanese Patent Application No. 2024-20368, filed on Feb. 14, 2024, which is expressly incorporated herein by reference in its entirety.

### TECHNICAL FIELD

The present invention relates to an electronic module.

### BACKGROUND ART

Conventionally, there has been known an electronic module that includes: a board; a heat generation part (for example, a semiconductor chip such as a MOSFET or the like) that is disposed on the board; and a mold resin that seals a surface of the board on a side where the heat generation part is disposed on the board and the heat generation part, wherein a surface of the board on a side opposite to a side where the heat generation part is disposed is exposed to the outside of the electronic module (for example, see patent literature 1).

In such a conventional electronic module, the surface of the board on the side opposite to the side of the board where the heat generation part is disposed is exposed to the outside of the electronic module and hence, heat generated from the heat generation part can be easily radiated to the outside of the electronic module via the board.

### PRIOR ART LITERATURE

### Patent Literature

[Patent Literature 1] WIPO 2020/208741

### SUMMARY OF INVENTION

### Technical Problem

A representative heat generation part in an electronic module is an electronic element. The study relating to electronic elements has been rapidly progressing recently and, for example, a next generation electronic element that uses SiC, GaN or the like as a semiconductor material has been put into practice. Such an electronic element enables downsizing (eventually high packaging) of the electronic element. On the other hand, with respect to these electronic elements, it is necessary to pay more attention to heat radiation property. Accordingly, in a technical field of an electronic module, there has been a demand for increasing heat radiation property of the electronic module.

The present invention has been made in view of the above-mentioned drawbacks, and it is an object of the present invention to provide an electronic module having higher heat radiation property than a conventional electronic module.

### Solution to Problem

An electronic module according to the present invention is an electronic module that includes: a first board; a first heat generation part that is disposed on the first board; and a mold resin that is configured to seal a surface of the first board on a side where the first heat generation part is disposed and the first heat generation part, wherein the electronic module further includes: a second board that is disposed on a side where the first heat generation part of the first board is disposed in a state where the second board is spaced apart from the first board and the first heat generation part; and a first heat transfer member that is configured to transfer heat generated from the first heat generation part to the second board, and a surface of the first board on a side opposite to a side where the first heat generation part is disposed, and a surface of the second board on a side opposite to a first board side are exposed to the outside of the electronic module.

### Advantageous Effects of the Present Invention

The electronic module according to the present invention includes: the second board that is disposed on the side where the first heat generation part of the first board is disposed in a state where the second board is spaced apart from the first board and the first heat generation part; and the first heat transfer member that is configured to transfer heat generated from the first heat generation part to the second board. Further, the surface of the first board on a side opposite to the side where the first heat generation part is disposed, and the surface of the second board on the side opposite to the first board side are exposed to the outside of the electronic module. With such a configuration, according to the electronic module of the present invention, heat generated from the first heat generation part can be radiated not only from the first board but also from the second board via the first heat transfer member. Accordingly, the electronic module according to the present invention forms an electronic module that can increase heat radiation property compared to a conventional electronic module.

### BRIEF DESCRIPTION OF DRAWINGS

FIG. 1 is a perspective view of an electronic module 1 according to an embodiment.

FIG. 2A to FIG. 2C are external appearances of the electronic module 1 according to the embodiment. FIG. 2A is a plan view of the electronic module 1. FIG. 2B is a left side view of the electronic module 1. FIG. 2C is a bottom view of the electronic module 1.

FIG. 3 is a perspective view of the internal structure of the electronic module 1 according to the embodiment. In FIG. 3, among constitutional elements of the electronic module 1, a mold resin 40 is not illustrated.

FIG. 4A and FIG. 4B are plan views illustrating the internal structure of the electronic module 1 according to the embodiment. FIG. 4A and FIG. 4B are plan views of the internal structure of the electronic module 1. In FIG. 4A, among the constitutional elements of the electronic module 1, a second board 20, a second heat generation part 22, a second spacer 25 and the mold resin 40 are not illustrated. In FIG. 4B, in addition to the constitutional elements not illustrated in FIG. 4A, a first heat transfer member 14, a first spacer 15, a first internal connection terminal 16, a first external connection terminal 30 and other external connection terminals 35 are not illustrated.

FIG. 5A to FIG. 5D are side views illustrating the internal structure of the electronic module 1 according to the embodiment. FIG. 5A is a left side view of the internal structure of the electronic module 1. FIG. 5B is a view illustrating the first heat transfer member 14 and an area in the vicinity of the first heat transfer member 14 in FIG. 5A in an enlarged manner. FIG. 5C is a right side view of the internal structure of the electronic module 1. FIG. 5D is a view illustrating a second heat transfer member 24 and an area in the vicinity of the second heat transfer member 24 in FIG. 5C in an enlarged manner. In FIG. 5A to FIG. 5D, among the constitutional elements of the electronic module 1, a first internal connection terminal 18, a second internal connection terminal 28, other external connection terminals 34, 37 and the mold resin 40 are not illustrated. Arrows H1 to H4 indicated by a broken line in FIG. 5B and FIG. 5D, indicate a mode of heat transfer (a mode of heat radiation) during an operation.

FIG. 6A and FIG. 6B are bottom plan views illustrating the internal structure of the electronic module 1 according to the embodiment. FIG. 6A and FIG. 6B are bottom plan views of the internal structure of the electronic module 1. In FIG. 6A, among the constitutional elements of the electronic module 1, a first board 10, a first heat generation part 12, a first spacer 15 and the mold resin 40 are not illustrated. In FIG. 6B, in addition to the constitutional elements not illustrated in FIG. 6A, the second heat transfer member 24, a second spacer 25, a second internal connection terminal 26, second external connection terminals 32a, 32b and other external connection terminal 36 are also not illustrated.

### DESCRIPTION OF EMBODIMENTS

Hereinafter, an electronic module according to the present invention is described based an embodiment illustrated in drawings. The embodiment described hereinafter is not intended to limit the invention called for in claims. Further, it is not always the case that all of various constitutional elements and combinations of these constitutional elements described in the embodiment are indispensable as means to solve the problems of the present invention.

### Embodiment

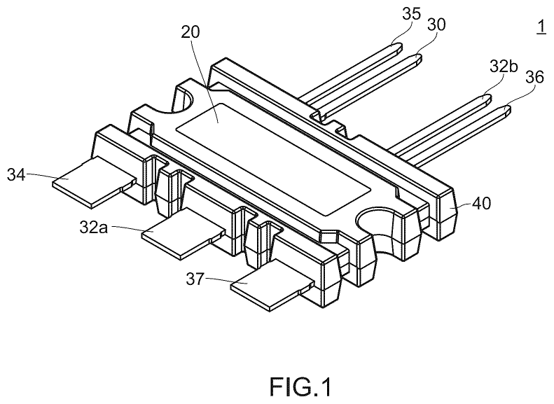

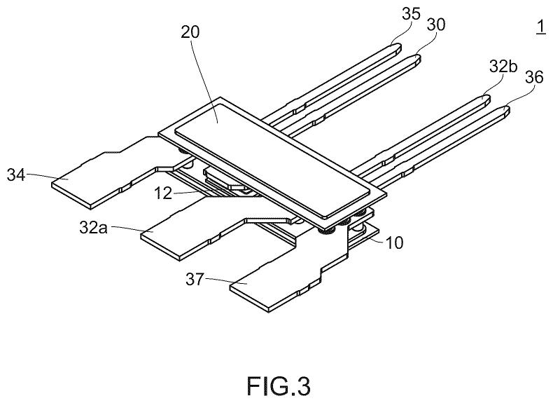

As illustrated in FIG. 1 to FIG. 6B, an electronic module 1 according to the embodiment includes: a first board 10; a first heat generation part 12; a first heat transfer member 14; a first spacer 15; first internal connection terminals 16, 18; a second board 20; a second heat generation part 22; a second heat transfer member 24; a second spacer 25; second internal connection terminals 26, 28; a first external connection terminal 30; second external connection terminals 32a, 32b; other external connection terminals 34, 35, 36, 37 and a mold resin 40. The electronic module 1 may include constitutional elements other than the above-mentioned constitutional elements. Hereinafter, the respective constitutional elements are described.

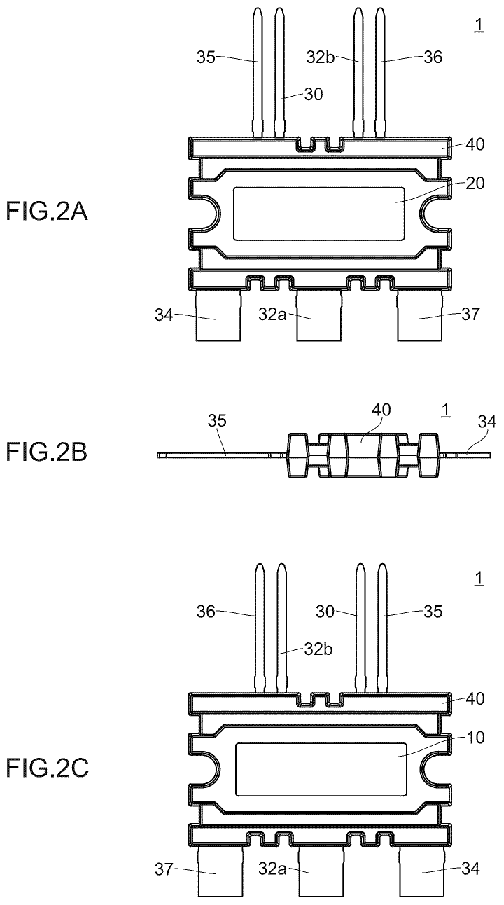

The first board 10 is a board on which the first heat generation part 12 is disposed. The first board 10 is a board having the structure where a copper plate is disposed on both surfaces of a ceramic plate (for example, DCB board). A surface of the first board 10 on a side opposite to a side where the first heat generation part 12 is disposed is exposed to the outside of the electronic module 1 (outside of the mold resin 40) (see FIG. 2C). The first board 10 is electrically connected with a first drain electrode (first second electrode, described later) of the first heat generation part 12.

In this specification, the expression “electrically connected” includes not only a case where electrically conductive portions of the constitutional elements are directly brought into contact with each other but also a case where the electrically conductive portions of the constitutional elements are brought into contact with each other by way of other conductive constitutional elements (for example, solder or spacer).

The first heat generation part 12 is disposed on the first board 10. In this specification, the term “heat generation part” means an electronic part from which heat is generated when the electronic part is used (when electricity is supplied to the electronic part). As the heat generation part, an electronic element (typically a semiconductor chip), a resistor, a coil and a capacitor can be exemplified. However, the heat generation part is not limited to the above-mentioned parts.

The first heat generation part 12 is a vertical electronic part that includes a first first electrode and a first second electrode. Here, “first first electrode” means a first electrode of a first heat generation part, and “first second electrode” means a second electrode of a first heat generation part. In this specification, “vertical electronic part” means an electronic part where at least two kinds of electrode (first electrode and second electrode) are disposed on a surface of the electronic part, and a surface on which the first electrode is disposed is a surface on a side opposite to a surface on which the second electrode is disposed. It may be also safe to say that “vertical electronic part” is a “an electronic part having an electrode on both surfaces”.

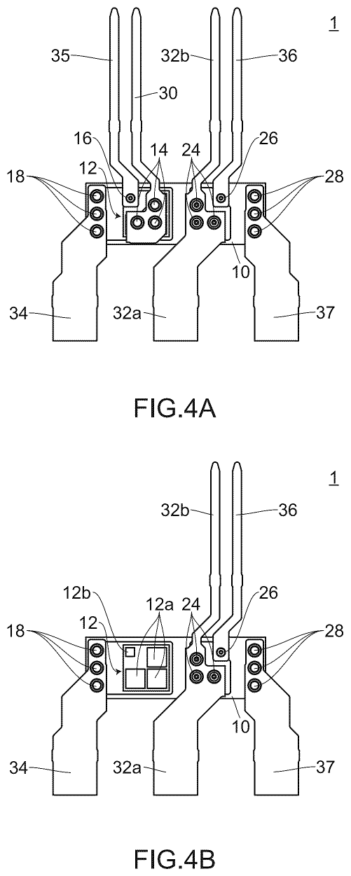

To be more specific, the first heat generation part 12 is a vertical metal-oxide semiconductor field-effect transistor (MOSFET) that includes: first source electrodes (first first electrodes) 12a disposed on a second board 20 side; a first drain electrode (first second electrode, not illustrated in the drawing) disposed on a first board 10 side; and a first gate electrode 12b disposed on the same side as the first source electrode 12a (see FIG. 4B). The first heat generation part 12 includes three first source electrodes 12a.

The first heat generation part 12 is a part that differs from the second heat generation part 22 with respect to heat generation timing. In this specification, the condition “differs in heat generation timing” is satisfied when the timing that the heat generation of the first heat generation part is increased or decreased and the timing that the heat generation of the second heat generation part is increased or decreased when these heat generation parts are actually used do not agree with each other. It is preferred that the “heat generation timing” is “timing that the heat generation becomes maximum”. In this case, the above-mentioned technical feature may be also expressed such that “at the time of using the electronic module 1, the first heat generation part 12 and the second heat generation part 22 are controlled such that the respective timings that the respective heat generation become maximum differ”. The electronic module 1 according to the embodiment constitutes a half bridge circuit and hence, the first heat generation part 12 is used to form a high side of the half bridge circuit and the second heat generation part 22 is used to form a low side of the half bridge circuit.

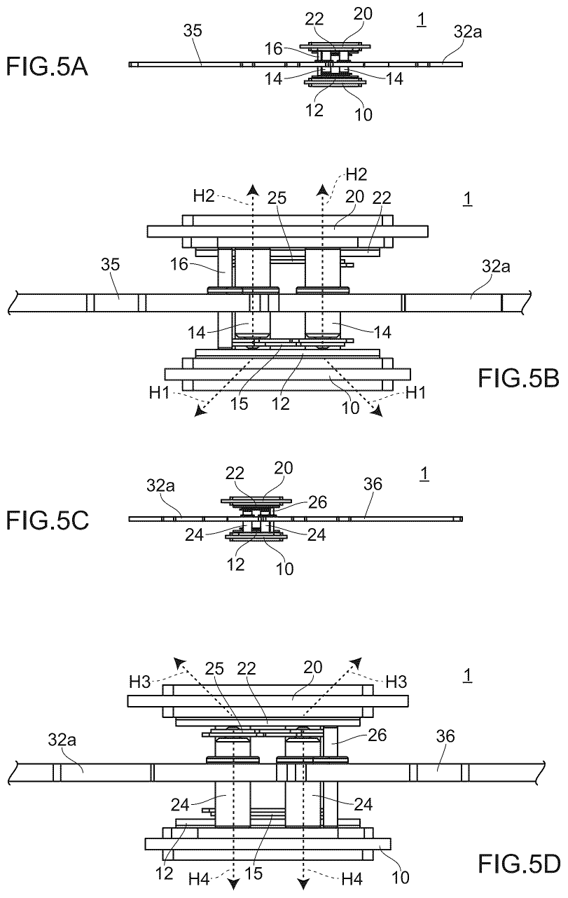

The first heat transfer member 14 is a member that transfers heat generated from the first heat generation part 12 to the second board 20 (see FIG. 5A and FIG. 5B). The first heat transfer member 14 is connected so that the first heat generation part 12 and the second board 20 perform the transaction of heat. The first heat transfer 14 is an approximately columnar member where a main portion is integrally formed. With respect to the first heat transfer member, the expression “connected such that the transaction of heat can be performed” includes not only a case where the first heat transfer member is directly brought into contact with a target member but also a case where the first heat transfer member is connected with the target member via a different member (for example, solder or spacer). It is preferred that the above-mentioned “another member” is made of a material having favorable thermal conductivity (for example, metal material). The same goes for the second heat transfer member with respect to the above-mentioned matter.

In this specification, as illustrated in FIG. 5B a mode of heat transfer (a mode of heat radiation) relating to the first heat generation part 12 in the electronic module 1 is described. The first heat generation part 12 is disposed on the first board 10. Accordingly, heat generated from the first heat generation part 12 is radiated to the outside of the electronic module 1 via the first board 10 (see an arrow H1).

The electronic module 1 includes the first heat transfer member 14 that transfers heat generated from the first heat generation part 12 to the second board 20. Accordingly, heat generated from the first heat generation part 12 is, besides a path via the above-mentioned first board 10, radiated to the outside of the electronic module 1 also via a path via the first heat transfer member 14 and the second board 20 (see the arrow H2).

The first heat transfer member 14 is made of a material having conductivity, and, is electrically connected with an electrode of the first heat generation part 12. That is, it is safe to say that the first heat transfer member 14 also has a function of an internal connection terminal that exists in the electronic module 1 and is used for electrical transaction. The first heat transfer member 14 is electrically connected with the first source electrodes (first first electrodes) 12a. The electronic module 1, includes three first heat transfer members 14 corresponding to a state where the first heat generation part 12 has three first source electrodes 12a. An end portion of the first heat transfer member 14 on a side opposite to the first heat generation part 12 side is electrically connected with a wiring pattern of the second board 20.

The first spacer 15 is made of a material having conductivity and is a dish-shaped member that is interposed between the first source electrodes 12a of the first heat generation part 12 and the first heat transfer member 14. Although not illustrated in the drawings, the first source electrodes 12a and the first spacer 15 are bonded to each other by bonding material having conductivity (for example solder). Further, the first spacer 15 and the first heat transfer member 14 are also bonded to each other by a bonding material having conductivity.

The first internal connection terminals 16, 18 are members that exist in the electronic module 1, and are used for electrical transaction. The first internal connection terminal 16 is electrically connected with the first gate electrode 12b of the first heat generation part 12 and other external connection terminal 35. The first internal connection terminal 18 is electrically connected with the first board 10 and other external connection terminal 34.

The second board 20 is a board that is disposed on a side where the first heat generation part 12 of the first board 10 is disposed in a state where the second board 20 is spaced apart from the first board 10 and the first heat generation part 12. With respect to the second board, the expression “a state where the second board is spaced apart from the first board and the first heat generation part” means a state where the second board is not directly brought into contact with the first board and the first heat generation part. Accordingly, so long as the second board is not directly brought into contact with the first board and the first heat generation part, even in a case where a constitutional element that is brought into contact with the second board is brought into contact with the first board or the first heat generation part, it is safe to say that the second board is “in a state where the second board is spaced apart from the first board and the first heat generation part”.

The second board 20 is a board having the structure where a copper plate is disposed on both surfaces of a ceramic plate (for example, DCB board). A surface of the second board 20 on a side opposite to a first board 10 side is exposed to the outside of the electronic module 1 (outside of the mold resin 40) (see FIG. 2A). The second board 20 is electrically connected with the second drain electrode (the second second electrode, described later) of the second heat generation part 22.

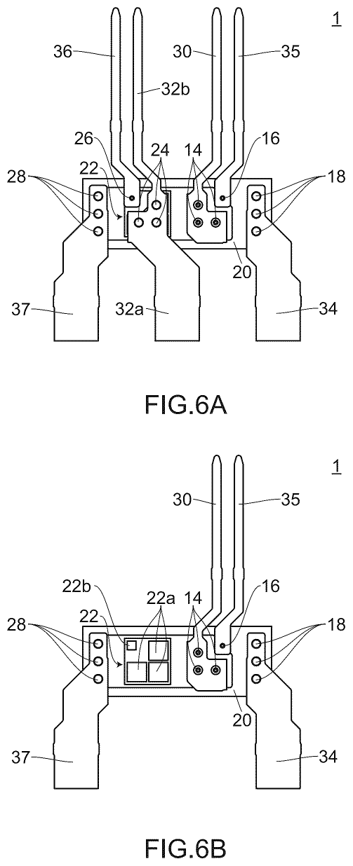

The second heat generation part 22 is disposed on a surface of the second board 20 on a first board 10 side. The second heat generation part 22 is a vertical electronic part that has a second first electrode and a second second electrode. Here, “second first electrode” means a first electrode of a second heat generation part, and “second second electrode” means a second electrode of a second heat generation part. To be more specific, the second heat generation part 22 is a vertical MOSFET that includes: second source electrodes (second first electrodes) 22a that are disposed on the first board 10 side; a second drain electrode (second second electrode, not illustrated in the drawing) that is disposed on a second board 20 side; and a second gate electrode 22b that is disposed on the same side as the second source electrodes 22a (see FIG. 6B). The second heat generation part 22 has three second source electrodes 22a.

The second heat transfer members 24 are members that transmit heat generated from the second heat generation part 22 to the first board 10 (see FIG. 5C and FIG. 5D). The second heat transfer member 24 is an approximately columnar member that is connected with the second heat generation part 22 and the first board 10 so as to allow the transaction of heat between the second heat generation part 22 and the first board 10, and a main part of the member is formed as an integral body.

In this specification, as illustrated in FIG. 5D a mode of heat transfer (a mode of heat radiation) relating to the second heat generation part 22 in the electronic module 1 is described. The second heat generation part 22 is disposed on the second board 20. Accordingly, heat generated from the second heat generation part 22 is radiated to the outside of the electronic module 1 via the second board 20 (see an arrow H3).

The electronic module 1 includes the second heat transfer member 24 that transfers heat generated from the second heat generation part 22 to the first board 10. Accordingly, heat generated from the second heat generation part 22 is, besides a path via the above-mentioned second board 20, is radiated to the outside of the electronic module 1 also via a path via the second heat transfer member 24 and the first board 10 (see an arrow H4).

The second heat transfer member 24 is made of a material having conductivity, and, is electrically connected with an electrode of the second heat generation part 22. That is, it is safe to say that the second heat transfer member 24 also has a function of an internal connection terminal that exists in the electronic module 1 and is used for electrical transaction. The second heat transfer members 24 are electrically connected with the second source electrodes (second first electrodes) 22a. The electronic module 1 includes three second heat transfer members 24 corresponding to a state where the second heat generation part 22 has three second source electrodes 22a. An end portion of the second heat transfer member 24 on a side opposite to a second heat generation part 22 side is electrically connected with a wiring pattern of the first board 10.

The second spacer 25 is made of a material having conductivity and is a dish-shaped member that is interposed between the second source electrode 22a of the second heat generation part 22 and the second heat transfer member 24. Although not illustrated in the drawings, the second source electrodes 22a and the second spacer 25 are bonded to each other by bonding material having conductivity (for example solder). Further, the second spacer 25 and the second heat transfer member 24 are also bonded to each other by a bonding material having conductivity.

The second internal connection terminals 26, 28 are members that exist in the electronic module 1, and are used for electrical transaction. The second internal connection terminal 26 is electrically connected with a second gate electrode 22b of the second heat generation part 22 and other external connection terminal 36. The second internal connection terminal 28 is electrically connected with the second board 20 and other external connection terminal 37.

The first external connection terminal 30 is electrically connected with the first heat transfer member 14 between the first board 10 and the second board 20, and at least one end of the first external connection terminal 30 protrudes to the outside of the mold resin 40. The first external connection terminal 30 in the electronic module 1 is a detection terminal with respect to the first source electrode 12a of the first heat generation part 12.

The second external connection terminals 32a, 32b are electrically connected with the second heat transfer member 24 between the first board 10 and the second board 20, and at least one ends of the second external connection terminals 32a, 32b protrude to the outside of the mold resin 40. The second external connection terminal 32a in the electronic module 1 is a power terminal compatible with a large current. Further, the second external connection terminal 32b of the electronic module 1 is a detection terminal with respect to the second source electrode 22a of the second heat generation part 22. The second external connection terminals 32a, 32b are respectively formed as an integral member.

Other external connection terminals 34, 35, 36, 37 are electrically connected with constitutional elements other than the first heat transfer member 14 and the second heat transfer member 24. At least one end of each external connection terminal protrudes to the outside of the mold resin 40. Other external connection terminal 34 is a power terminal electrically connected with the first internal connection terminal 18. Other external connection terminal 35 is a control terminal electrically connected with the first internal connection terminal 16. Other external connection terminal 36 is a control terminal electrically connected with the second internal connection terminal 26. Other external connection terminal 37 is a power terminal electrically connected with the second internal connection terminal 28.

The mold resin 40 is a member that seals a surface of the first board 10 on a side where the first heat generation part 12 is disposed and the first heat generation part 12 (see FIG. 1 and FIG. 2A to FIG. 2C). Further, the mold resin 40 also seals a surface of the second board 20 on a side where the second heat generation part 22 is disposed and the second heat radiation part 22.

Hereinafter, advantageous effects of the electronic module 1 according to the embodiment are described.

The electronic module 1 according to the embodiment includes: the second board 20 that is disposed on a side where the first heat generation part 12 is disposed in a state where the second board 20 is spaced apart from the first board 10 and the first heat generation part 12; and the first heat transfer member 14 that transfers heat generated from the first heat generation part 12 to the second board 20. Further, the surface of the first board 10 on the side opposite to the side where the first heat generation part 12 is disposed, and the surface of the second board 20 on the side opposite to the first board 10 side are exposed to the outside of the electronic module 1. With such a configuration, according to the electronic module 1 of the embodiment, heat generated from the first heat generation part 12 can be radiated not only from the first board 10 but also from the second board 20 via the first heat transfer member 14. Accordingly, the electronic module 1 according to the embodiment forms an electronic module that can increase heat radiation property compared to a conventional electronic module.

Further, in the electronic module 1 according to the embodiment, the first heat generation part 12 has electrodes, and the first heat transfer member 14 is made of a conductive material, and is electrically connected with the electrode of the first heat generation part 12. With such a configuration, according to the electronic module 1 of the embodiment, it is possible to use the first heat transfer member 14 for enabling electrical transaction between the first heat generation part 12 and the other constitutional element. Accordingly, functions of the constitutional elements can be collected and hence, downsizing of the electronic module 1 can be realized.

Further, in the electronic module 1 according to the embodiment, the first heat generation part 12 is a vertical electronic part having the first source electrodes (first first electrodes) 12a and the first drain electrode (first second electrode), the first heat transfer member 14 is electrically connected with the first source electrode 12a, and the first board 10 is electrically connected with the first drain electrode. With such a configuration, according to the electronic module 1 of the embodiment, with the use of the vertical electronic part that includes the electrodes on both surfaces as the first heat generation parts 12, both of the enhancement of heat radiation property and downsizing can be realized.

Further, the electronic module 1 according to the embodiment includes the first external connection terminal 30 that is electrically connected with the first heat transfer member 14 between the first board 10 and the second board 20. With such a configuration, according to the electronic module 1 of the embodiment, it is possible to directly take out a current from the first heat transfer member 14 via the first external connection terminal 30.

The electronic module 1 according to the embodiment includes: the second heat generation part 22 that is disposed on the surface of the second board 20 on a first board 10 side; and the second heat transfer member 24 that transfers heat generated from the second heat generation part 22 to the first board 10. With such a configuration, according to the electronic module 1 of the embodiment, the second heat generation part 22 can be also disposed on the second board 20 and hence, packing density can be increased and, at the same time, heat radiation property can be also increased with respect to the second heat radiation part 22.

Further, according to the electronic module 1 of the embodiment, the second heat generation part 22 has the electrodes, and the second heat transfer member 24 is made of a conductive material, and is electrically connected with the electrode of the second heat radiation part 22. With such a configuration, according to the electronic module 1 of the embodiment, the second heat transfer member 24 can be used for performing the electrical transaction between the second heat generation part 22 and the other constitutional elements and hence, functions of the constitutional elements can be collected whereby downsizing of the electronic module 1 can be realized.

Further, according to the electronic module 1 of the embodiment, the second heat generation part 22 is the vertical electronic part having the second source electrodes (second first electrodes) 22a and the second drain electrode (second second electrode), the second heat transfer member 24 is electrically connected with the second source electrode 22a, and the second board 20 is electrically connected with the second drain electrode. With such a configuration, according to the electronic module 1 of the embodiment, with the use of the vertical electronic part having electrodes on both surfaces as the second heat generation part 22, both of the enhancement of heat radiation property and downsizing can be realized.

Further, the electronic module 1 according to the embodiment includes the second external connection terminals 32a, 32b that are electrically connected with the second heat transfer member 24 between the first board 10 and the second board 20. With such a configuration, according to the electronic module 1 of the embodiment, a current can be directly taken out from the second heat transfer member 24 via the second external connection terminals 32a, 32b.

Further, according to the electronic module 1 of the embodiment, heat generation timing of the first heat generation part 12 differs from heat generation timing of the second heat generation part 22. With such a configuration, according to the electronic module 1 of the embodiment, timing at which heat is generated can be displaced between the first heat generation part 12 and the second heat generation part 22. Accordingly, heat generated temporarily in the electronic module 1 can be reduced.

Further, in the electronic module 1 according to the embodiment, the first board 10 and the second board 20 adopt the structure where a copper plate is disposed on both surfaces of a ceramic plate. As a result, according to the electronic module 1 of the embodiment, heat radiation property can be further increased by using the board having high heat conductivity.

Although the present invention has been described based on the above-mentioned embodiment heretofore, the present invention is not restricted to the above-mentioned embodiment. The present invention can be carried out in various modes without departing from the gist of the present invention. For example, the following modifications are also conceivable.

(1) The shapes, the numbers, the sizes, the positions and the like of the constitutional elements of the present invention are not limited to values described in the above-mentioned description and the respective drawings, and these values can be suitably changed so long as the technical feature of the present invention are not impaired.

To exemplify one example, although the number of first heat generation part 12 is one in the above-mentioned embodiment, the present invention is not limited to such an example. The number of the first heat generation parts may be plural. The above-mentioned matter is also applicable to the second heat generation part in the same manner.

(2) The electronic module according to the present invention may further include heat generation parts other than the first heat generation part (heat generation parts that do not have corresponding first heat transmission members) or other structures on the first board. Further, the electronic module according to the present invention may further include heat generation parts other than the second heat generation part (heat generation parts that do not have corresponding second heat transmission members) or other structures on the second board.

(3) The electronic module according to the present invention may include neither the second heat generation part nor the second heat transfer member.

(4) The electronic module according to the present invention may include neither the first spacer nor the second spacer.

(5) In the above-mentioned embodiment, the first external connection terminal 30 is the detection terminal, the second external connection terminal 32b is the power terminal, and the second external connection terminal 32a is the detection terminal. However, the present invention is not limited to such a configuration. Functions of the respective external connection terminals can be suitably set corresponding to the structure or the like of the electronic module.

(6) As the first heat generation part in the electronic module according to the present invention, a heat generation part other than the vertical MOSFET can be also used. As the heat generation part other than the vertical MOSFET, an electronic element other than the vertical MOSFET (diode, transistor, thyristor or the like), a register, a coil, and a capacitor can be exemplified. The above-mentioned matters are also applicable to the second heat generation part.

1. An electronic module comprising:
a first board;
a first heat generation part that is disposed on the first board; and
a mold resin that is configured to seal a surface of the first board on a side where the first heat generation part is disposed and the first heat generation part, wherein
the electronic module further comprises:
a second board that is disposed on a side where the first heat generation part of the first board is disposed in a state where the second board is spaced apart from the first board and the first heat generation part; and
a first heat transfer member that is configured to transfer heat generated from the first heat generation part to the second board, and
a surface of the first board on a side opposite to a side where the first heat generation part is disposed, and a surface of the second board on a side opposite to a first board side are exposed to the outside of the electronic module.

2. The electronic module according to claim 1, wherein, the first heat generation part has an electrode, and
the first heat transfer member is made of a conductive material, and is electrically connected with the electrode of the first heat generation part.

3. The electronic module according to claim 2, wherein the first heat generation part is a vertical electronic part having a first first electrode and a first second electrode,
the first heat transfer member is electrically connected with the first first electrode, and
the first board is electrically connected with the first second electrode.

4. The electronic module according to claim 2, further comprising: a first external connection terminal that is electrically connected with the first heat transfer member between the first board and the second board.

5. The electronic module according to claim 1, further comprising: a second heat generation part that is disposed on the surface of the second board on a first board side; and
a second heat transfer member that is configured to transfer heat generated from the second heat generation part to the first board.

6. The electronic module according to claim 5, wherein the second heat generation part has an electrode, and
the second heat transfer member is made of a conductive material, and is electrically connected with the electrode of the second heat generation part.

7. The electronic module according to claim 6, wherein the second heat generation part is a vertical electronic part having a second first electrode and a second second electrode,
the second heat transfer member is electrically connected with the second first electrode, and
the second board is electrically connected with the second second electrode.

8. The electronic module according to claim 6, further comprising a second external connection terminal that is electrically connected with the second heat transfer member between the first board and the second board.

9. The electronic module according to claim 5, wherein heat generation timing of the first heat generation part differs from heat generation timing of the second heat generation part.

10. The electronic module according to claim 1, wherein the first board and the second board adopt the structure where a copper plate is disposed on both surfaces of a ceramic plate.
